(19) United States
(12) Patent Application Publication
(10) Pub. No.: US 2008/0080655 A1
(43) Pub. Date: Apr. 3, 2008

(54) PRECISE FREQUENCY RAIL TO RAIL SPREAD SPECTRUM GENERATION

(75) Inventors: Don A. Gilliland, Rochester, MN (US); Timothy L. McMillan, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/537,777

(22) Filed: Oct. 2, 2006

(51) Int. Cl. H03D 3/24

(52) U.S. Cl. 375/376

(57) ABSTRACT

A method and circuit for generating a spread spectrum that will allow for precise control of the upper and lower frequencies of the fundamental to control the spread at the harmonics. The spread spectrum generation circuit of this invention includes a first clock producing a first frequency, a second clock producing a second frequency, the second frequency being set to a different frequency from the first frequency the second frequency being set to a different frequency from the first frequency. The circuit includes a phase locked loop circuit and the phased lock loop circuit includes a phase detector and the second clock. Following the phase locked loop circuit is a post divider that receives its input signal from the output of phase locked loop and then sends its output signal to an amplifier. The amplifier is used to amplify the input signal to produce an output signal that is the spread spectrum clock output for the circuit.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

The present invention relates to the field of spread spectrum clock generation and more particularly, to a method and system for generating a spread spectrum clock.

2. Description of the Related Art

Generation of spread spectrum clock signals is usually performed using a phase locked loop (PLL) circuit. Typically, the generation is achieved by modulating a feedback loop using one of an internal modulator and an external modulator. The internal modulator is usually derived by a dividing circuit that sets the percent spread to certain values. Values that are commonly used in the commercial market are 1, 2, 5, 0.5 and 0.25 percent; with the 0.25 percent value being the lowest percentage found. However, this is frequently inadequate for current applications.

For example, consider one standard, referred to as “InfiniBand.” InfiniBand is an interconnect standard for servers, and is provided by the InfiniBand Trade Association of Portland Oreg. InfiniBand architecture provides for throughput of 2.5 Gbits/sec, 10 Gbits/sec, and 30 Gbits/sec. Accordingly, tight controls are required for the fundamental frequency of data signals.

Unfortunately, use of spread spectrum clocks to produce the fundamental frequency does not permit some systems (such as those employing the Infiniband standard) to operate within the design specifications. In fact, these problems are further complicated when accounting for harmonic signals.

Many of the available spread spectrum clocks are only able to process the harmonics of the data signal that are 1 GHz or below. Therefore, they are not able to support the new design specifications like Infiniband that require processing above the 1 GHz ceiling. For processing signals above the 1 GHz ceiling, the harmonic signals need to be spread and not the fundamental signal. When the harmonics are used instead of the fundamental frequency, the spread at the fundamental frequency does not have to be as wide because the harmonics are spread at a rate of N*fundamental. Therefore, by spreading the harmonic frequency of the data signals above the 1 GHz only a 1.2 MHz spread is needed to exceed the bandwidth of the measuring receiver.

Therefore, it would be desirable to have the ability to precisely control the upper and lower frequencies of the fundamental frequency in order to control the spread of harmonic frequencies. For example, when considering Infiniband, a 2.5 GHz harmonic is the 20th harmonic of the fundamental frequency for a 125 MHz input clock. To spread the 2.5 GHz harmonic by 1.2 MHz, the clock needs to be spread by +/−0.0024% which is not possible with the 0.25% now available as the minimum.

What is also needed is an ability to precisely control the fundamental frequency of a clock. Preferably, the ability provides for controlling the frequency over a negative and positive range, and provides a fundamental clock frequency that meets the needs of increasingly demanding standards, such as Infiniband.

### SUMMARY OF THE INVENTION

The shortcomings of the prior art are overcome and additional advantages are provided through the provision of a spread spectrum generation circuit that will allow for precise control of the upper and lower frequencies of the fundamental frequency in order to control the spread at the harmonics. The spread spectrum generation circuit of this invention includes a first clock producing a first frequency; a second clock producing a second frequency; the second frequency being set to a different frequency from the first frequency; a phase locked loop circuit, the phase locked loop circuit includes a phase detector and the second clock; a post divider, the post divider receiving its input signal from the output of phase locked loop circuit; and an amplifier, used to amplify the output signal from the phase locked loop circuit, wherein the output signal of the phase locked loop circuit after being processed by the post divider and the amplifier produces the spread spectrum generation circuit output.

Also disclosed is a method for generating a spread spectrum, includes generating a first frequency from a first clock; generating a second frequency from a second clock, the second frequency being set to a different frequency from the first frequency; outputting the selected clock frequency into a phase locked loop circuit, the phase locked loop circuit having at least a phase detector and the second clock; controlling a spread spectrum modulation so that an output frequency is produced by selecting from either the first clock frequency or the second clock frequency, the output frequency modulation being set to a value between the first clock frequency and the second clock frequency by processing the selected clock frequency by a phase locked loop circuit, dividing the output of the phased locked loop circuit by a post divider, the post divider providing a divider output signal; and amplifying the input signal from the post divider and providing an amplified output signal, wherein the output signal of the amplifier is the spread spectrum clock output.

System and computer program products corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a diagram showing the configuration of a spread spectrum generation circuit according to one embodiment of the present invention;

FIG. 2 is a flowchart illustrating one method for implementing the circuit shown in FIG. 1, and

FIG. 3 is a block diagram showing aspects of the architecture of the present invention.

The detailed description explains the preferred embodiments of the invention, together with advantages and features, by way of example with reference to the drawings.

### DETAILED DESCRIPTION OF THE INVENTION

The following is intended to provide a detailed description of an example of the invention and should not be taken to be limiting itself. Rather, any number of variations may fall within the scope of the invention, which is defined in the claims following the description. The nature, objectives, and advantages of the invention will become more apparent to those skilled in the art after considering the following detailed description in connection with the accompanying drawings.

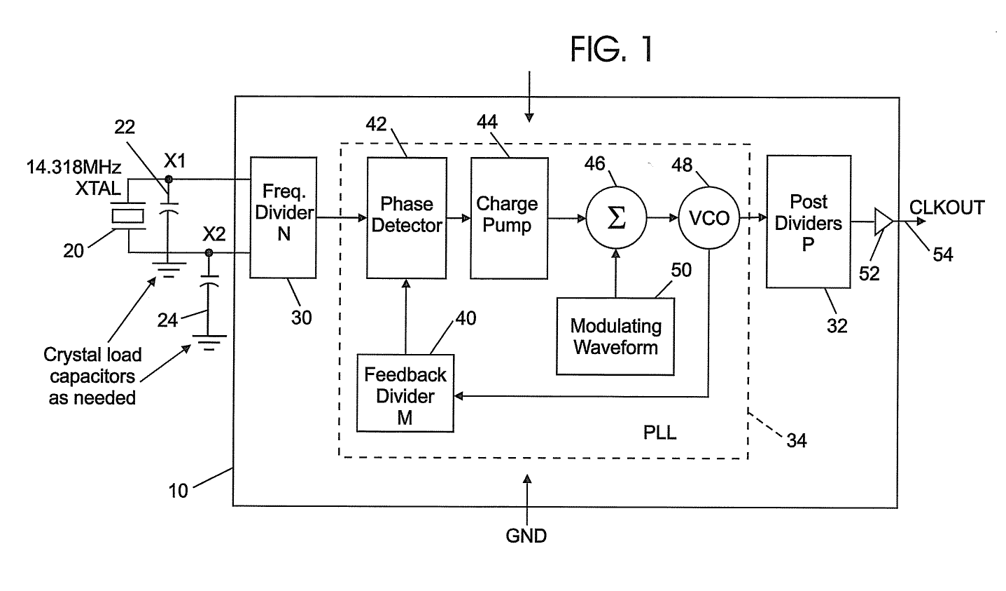

Referring now to FIG. 1, an embodiment of a spread spectrum generation circuit 10 is depicted. An input oscillator (XTAL) clock 20 provides an input signal for the spread spectrum generation circuit 10. In FIG. 1, the input oscillator clock 20 is set to a frequency of 14.318 MHZ. Optional crystal load capacitors 22 and 24, can be added as needed after the input oscillator clock 20 and prior to the input signal entering the spread spectrum generation circuit 10. In FIG. 1, the two crystal load capacitors 22 and 24 are used to stabilize input oscillations produced by the input oscillator 20.

Historically, the term “rail to rail” is referred to voltage constraints on a circuit. It is understood that the voltage levels should not exceed these supply values. However, in this case the term “rail to rail” refers to the frequencies that are set by the oscillators that are essentially “stopping” points for the spread. Because these frequencies are set by discrete oscillators and not swept they can be considered limits within the frequency spectrum that set the bandwidth of the spread (i.e. rail to rail in this instance refers to frequency stop points not voltage stop points).

In the embodiment of FIG. 1, the spread spectrum generation circuit 10 includes a first clock, the first clock being a frequency divider 30 and producing a first frequency, a second clock, the second clock being a feedback divider 40 and producing a second frequency, a phase lock loop (PLL) circuit 34, the phase lock loop circuit 34 including the second clock 30, a post divider 32 and an amplifier 52 for producing the spread spectrum generation circuit output 54. The frequency divider 30 receives input signals from the input oscillator clock 20 after passing the input signals through the crystal load capacitors 22 and 24.

The phase locked loop circuit 34 is a closed loop frequency system that operates based on the phase sensitivity detection of the phase difference between the input and output signals of a voltage controlled oscillator 48. The phase locked loop circuit 34 can make use of a blend of digital signals and analog signals.

In the embodiment depicted FIG. 1, the phase locked loop circuit 34 includes a phase detector 42, a charge pump 44, a summer 46, a modulating waveform generator 50, the voltage controlled oscillator 48, and the feedback divider 40. The phase detector 42 receives the input signals that are sent to the phase locked loop circuit 34, even though the phase detector 42 is inside the phase locked loop circuit 34.

The phase detector 42 is a device that compares two input frequencies and generates an output that is a measure of their phase difference. In the case where the two input signals are equal in phase and frequency, then the phase detector 42 will produce no output. However, if the two input signals are not in phase and frequency, the difference is converted to a DC output from the phase detector 42. In the case where the two input signals differ in frequency, then the phase detector 42 produces a signal with a periodic output at the difference frequency. The greater the frequency and phase difference in the two input signals then the larger the output voltage.

In FIG. 1, the phase detector 42 is used to select between the first clock input signal provided by the frequency divider 30 and the second clock input signal provided by the frequency divider 40 and then outputs an output signal from the selected clock into a phase locked loop circuit 34. The phase detector 42 receives inputs from both the frequency divider 30 and the feedback divider 40 with the feedback divider 40 being a component of the phased locked loop circuit 34. The phase detector 42 is controlled by a spread modulation controller, the spread modulation controller being a voltage controlled oscillator 48. The phase detector 42 produces an output signal that is the input signal of the charge pump 44.

The charge pump 44 is the controller that allows the phased lock loop circuit 34 to stay locked on to the crystal frequency oscillator 20 frequency and to allow for a smooth change from one frequency to another at the selected modulation rate. The modulation rate is determined and set by the modulating waveform generator 50. A summer 46 sums combines the signals from the output of the charge pump 44 and signal generated and output from the modulating waveform generator 50 and then produces an output signal.

The voltage controlled oscillator 48 receives as an input signal the output from the summer 46. If the voltage controlled oscillator 48 receives a signal, f-in, from the summer 48 and f-in is not equal to f-out, where f-out is the signal output from the voltage controlled oscillator 48, then the phase error signal generated by the difference of the two input signals will cause the voltage controlled oscillator 48 frequency to deviate in the direction of f-in. If the conditions are right, the voltage controlled oscillator 48 will quickly lock to f-in and therefore will maintain a fixed relationship with the input signal generated by the crystal oscillator 20. The output signal from the voltage controlled oscillator 48 provides an output signal to both the phase locked loop circuit 34 and the post divider 32. The voltage controlled oscillator 48 also provides an output signal to be used as the input signal into the feedback divider 40. By placing the feedback divider 40 between the voltage controlled oscillator 48 and the phase detector 42, clock pulses can be generated.

The spread spectrum clock output 54 is produced by altering the low frequency difference signal, adding an offset within the PLL circuit 34 thereby changing the frequency from the voltage controlled oscillator 48 and therefore allowing the signal to spread. The frequency of the spread spectrum clock output 54 is accurately controlled by the phase detector 42 to be between the first frequency and the second frequency (or some factor of the first and second frequency, depending on the details of the phase locked loop circuit 34).

To implement the spread spectrum clock circuit 10 precise XO's (crystal oscillators) are used in the frequency divider 30 and the feedback divider 40 with the values chosen to set the edges of the maximum and minimum frequency. In FIG. 1 the XO's are shown as X1 and X2. For the infiniband case, the XO's chosen are 125.03 MHz and 124.97 MHz. These oscillators can be purchased on the market in either single or dual packages. The upper and lower frequencies of the fundamental and are used to control the “rail to rail” spread at the harmonics.

A modulation frequency (between 17 and 120 k Hz, 32typ) can be used to switch between the two running oscillators. This establishes the spread bandwidth. However, to keep the spread spectrum from “jumping” between frequencies with the risk of “loss of lock”, the output is followed by a phase locked loop that has a controllable loop filter and/or charge pump control 44 that allows the phase locked loop to stay locked and smoothly change from one frequency to another at the modulation rate.

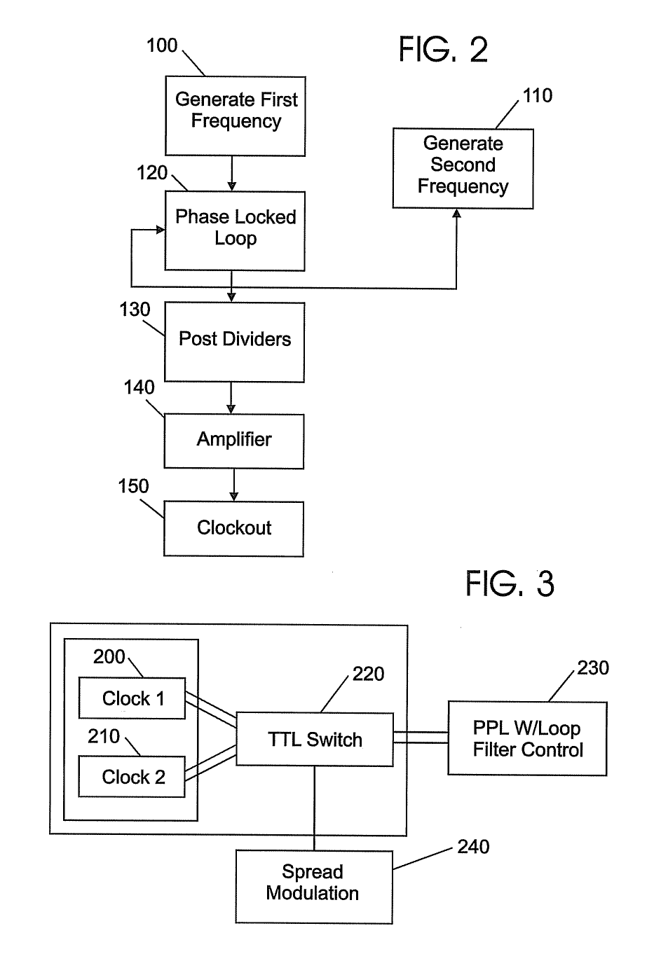

Referring to FIG. 2, there is shown a flow diagram on one embodiment in accordance with the present invention shown in FIG. 1. The following summarizes the above invention in several steps. One scenario is as follows. A first signal is generated 100 and is sent to the phase locked loop 120 for processing. The phase lock loop 120 receives the first input signal from the first clock and processes it. After processing the first signal, the phase locked loop 120 sends the signal out to both the feedback divider inside the phased locked loop 120 to generate the second signal 110 and to the post divider 130. From the post divider 130 divides the signal down and then sends it to the amplifier 140 before it sends it out of the spread spectrum circuit as clockout 150. The cycle then begins with a first signal being generated 100 and a second signal being generated 110 and processed by the phased lock loop 120 to repeat the cycle of processing before it is sent out as clockout 150.

Referring to FIG. 3 there is shown a block diagram of one embodiment in accordance with the present invention shown in FIG. 1. The following summarizes the block diagram of this architecture. The first signal is generated by the first clock 200 and is shown in FIG. 1 as the frequency divider 30 and the second signal is generated by the second clock 210 and is shown as the feedback divider 40. The signals from clock 1 200 and clock 2 210 are input into a transistor-transistor logic (TTL) switch 220 for selection after being switched are then output to a phase locked loop control 230 and as an output spread modulation signal 240.

The capabilities of the present invention can be implemented in software, firmware, hardware or some combination thereof. Portions of the spread spectrum generation circuit can be implemented in software. One example would allow the filter embedded in the charge pump to be written in software so that the filter coefficients could be easily changed through a computer program. By being able to change the filter coefficients in software, will allow the user to make adjustments to the circuit without having to modify any hardware components. Another example could be to have the any of the frequency divider, the feedback divider or the post divider to be controlled by software so that it would be easy to change any of the integers used in the dividers.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

This spread spectrum circuit will provide a tighter percentage spread of the fundamental and therefore allow for the processing of operating frequencies such as the InfiniBand. In addition, technically we have achieved a solution that will allow the output to be driven “rail to rail”.

Ultimately the whole architecture for this circuit can be placed into one module that should only need 6 pins that is the footprint industry standard for surface mount crystal oscillators and therefore not only provide a cost savings but provide for usability. The 6 pins would be to provide for power, ground, out+, out−, loop_lowZ, loop_highZ.

Additionally, at least one program storage device readable by a machine, tangibly embodying at least one program of instructions executable by the machine to perform the capabilities of the present invention can be provided.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A spread spectrum generation circuit comprising:
a first clock producing a first frequency;
a second clock producing a second frequency, the second frequency being set to a different frequency from the first frequency;
a phase locked loop (PLL) circuit, the phase locked loop circuit including a phase detector and the second clock;
a post divider, the post divider receiving an input signal from the PLL output; and
an amplifier, used to amplify the PLL output, wherein the PLL output is processed by the post divider and the amplifier to produce the spread spectrum generation circuit output.

2. The spread spectrum generation circuit of claim 1, wherein the first clock comprises a frequency divider.

3. The spread spectrum generation circuit of claim 1, wherein the second clock comprises a feedback divider.

4. The spread spectrum generation circuit of claim 1, wherein the phase locked loop circuit further comprises at least one charge pump.

5. The spread spectrum generation circuit of claim 1, wherein the phase locked loop circuit further comprises: a charge pump, the charge pump receiving the output from the phase detector and providing an output signal; a modulating waveform generator for generating a modulated waveform; a summer for receiving input from the modulation waveform generator and the charge pump; a voltage controlled oscillator, the voltage controlled oscillator receiving an input from the summer and providing an output signal from the phase locked loop circuit to the post divider.

6. A spread spectrum generation circuit comprising:
a frequency divider producing a first frequency;
a feedback divider producing a second frequency, the second frequency being set to a different frequency from the first frequency;
a phase locked loop circuit, the phase locked loop circuit comprises a phase detector; a charge pump; a summer, a modulating waveform generator, a voltage controlled oscillator, and the feedback divider;
a post divider, the post divider receiving its input signal from the output of phase locked loop circuit; and
an amplifier, used to amplify the output signal from the phase locked loop circuit, wherein the output signal of the phase locked loop circuit after being processed by the post divider and the amplifier produces the spread spectrum generation circuit output.

7. A method for generating a spread spectrum comprising:
generating a first frequency from a first clock;
generating a second frequency from a second clock, the second frequency being set to a different frequency from the first frequency;
outputting the selected clock frequency into a phase locked loop circuit, the phase locked loop circuit includes at least a phase detector and the second clock;
controlling a spread spectrum modulation so that an output frequency is produced by selecting from either the first clock frequency or the second clock frequency, the output frequency modulation being set to a value between the first clock frequency and the second clock frequency by processing the selected clock frequency by a phase locked loop circuit,
dividing the output of the phased locked loop circuit by a post divider, the post divider providing a divider output signal; and
amplifying the input signal from the post divider and providing an amplified output signal, wherein the output signal of the amplifier is the spread spectrum clock output.

8. The method as in claim 7, wherein the spread spectrum clock output is controlled rail to rail.

9. The method as in claim 7, wherein generating a first frequency comprises using a frequency divider.

10. The method as in claim 7, wherein generating a second frequency comprises using a feedback divider.

11. The method as in claim 7, wherein the phase lock loop circuit further comprises: a charge pump, the charge pump receiving the output from the phase detector and providing a filtered output; a modulating waveform generator for generating a modulating waveform; a summer, the summer receiving input from the modulation waveform generator and the output of the charge pump; and a voltage controlled oscillator, the voltage controlled oscillator receiving an input from the summer and providing an output signal from the phase locked loop to the post divider.
